(19) United States
(12) Patent Application Publication
(10) Pub. No.: US 2024/0324437 A1
(43) Pub. Date: Sep. 26, 2024

(54) TUNABLE POLYMER TRANSPORT MATERIALS FOR APPLICATION IN PEROVSKITE SOLAR CELLS

(71) Applicant: Colorado School of Mines, Golden, CO (US)

(72) Inventors: Alan Sellinger, Lafayette, CO (US); Daniel Astridge, Westminster, CO (US); Jacob Levin, Denver, CO (US)

(21) Appl. No.: 18/614,390

(22) Filed: Mar. 22, 2024

Related U.S. Application Data
(60) Provisional application No. 63/453,972, filed on Mar. 22, 2023.

(51) Int. Cl. H10K 85/10; H10K 30/50; H10K 30/86; H10K 71/15; H10K 85/50; H10K 101/30

(52) U.S. Cl. CPC H10K 85/111; H10K 30/50; H10K 30/86; H10K 71/15; H10K 85/50; H10K 2101/30

(57) ABSTRACT

Polymer transport materials for application in perovskite solar cells capable of being tuned or manipulated to achieve desired properties, are provided herein. The present disclosure is directed to methods, systems, and compositions for achieving polymer transport materials (i.e., hole transport materials (HTMs)) with desirable properties such as solution processability, energy level tuning (i.e., adjusting), high thermal properties, tunable (i.e., adjustable) wettability, and perovskite defect passivation. In some aspects of the present disclosure, the synthesis of such HTMs may be implemented via relatively simple and inexpensive processes.

### CROSS-REFERENCE TO RELATED APPLICATIONS

The present application claims the benefits of U.S. Provisional Application Ser. No. 63/453,972, filed Mar. 22, 2023, entitled “TUNABLE POLYMER TRANSPORT MATERIALS FOR APPLICATION IN PEROVSKITE SOLAR CELLS,” which is incorporated herein by reference in its entirety.

### STATEMENT REGARDING FEDERALLY SPONSORED RESEARCH

This invention was made with government support under grant number DE-EE0008978 awarded by the United States Department of Energy. The government has certain rights in the invention.

### FIELD OF INVENTION

The present disclosure relates generally to polymer transport materials such as hole transport materials (HTMs), and particularly to polymer transport materials for application in perovskite solar cells (PSCs) capable of being tuned or manipulated to achieve properties beneficial for the function of a PSC.

### BACKGROUND

A perovskite solar cell (PSC) is a type of solar cell that includes a perovskite-structured compound, most commonly a hybrid organic-inorganic lead or tin halide-based material as the light-harvesting active layer. PSCs are promising light-harvesting devices due to their high efficiencies, facile integration into tandem devices, and high potential for low-cost manufacturing due to simple processing techniques, such as roll-to-roll printing.

In general, PSCs can be classified into two architecture types, NIP and PIN, where the difference is defined by the order of deposition of the electron and hole selective contacts relative to the transparent conductive oxide (TCO) substrate. PSCs include hole-transport materials (HTMs), which play a vital role in both device stability and efficiency by facilitating hole extraction and suppressing charge recombination between the anode and perovskite layers while assisting in charge separation and conduction of holes to the cathode of the PSCs. For example, PIN devices are fabricated so that light can pass through multiple layers prior to reaching the active perovskite layer, where it is eventually absorbed. These layers include the glass protective layer, anode, and HTM.

Organic materials are often selected as HTMs because of their tunable thermal and optoelectronic properties, as well as their ability to be vacuum- and/or solution-processed into devices. Most commonly, these organic materials comprise small molecules and polymers containing the triarylamine moiety, which can be modified to match device needs. (Poly)arylamine-based materials are a frequent choice for HTMs in PSCs due to their electron-rich nature and high excited-state stability, which is attributable to resonance in adjacent conjugated groups. The current benchmark materials for both NIP and PIN devices are poly[bis(4-phenyl)-(2,4,6-trimethylphenyl)amine] (PTAA), 2,2′,7,7′-tetrakis(N,N-di-p-methoxyphenylamine)-9,9′-spirobiflurorene (spiro-OMeTAD), poly(3,4-ethylenedioxythiophene) polystyrene sulfonate (PEDOT:PSS), [2-(9H-carbazol-9-yl)ethyl]phosphonic acid (2PACz), and poly(3-hexylthiophene-2,5-diyl) (P3HT).

Each of these materials, while highly efficient, presents its own problems. For example, PTAA, spiro-OMeTAD, and 2PACz are prohibitively expensive for commercial applications, while PEDOT:PSS is highly acidic and hydrophilic, which is problematic for long-term device stability. Spiro-OMeTAD and other organic small molecules require doping for high efficiencies and cannot be incorporated into PIN architectures, as the HTM layer is destroyed due to its solubility in the perovskite precursor. Further, self-assembled monolayers (SAMs) of phosphonic acids like 2PACz are typically only useful for PIN-type devices.

Further, because of the variation in band gap and band edge energies of the perovskite family, having HTMs with complementary properties becomes imperative. PTAA cannot be modified, however, so PTAA has a narrow range of usability with perovskites before its highest occupied molecular orbital (HOMO) energy is an energetic mismatch with the valence band of the absorber. For example, PTAA and P3HT have unique HOMO levels that are only compatible with certain perovskite formulations, whereas perovskites with narrow band gaps have shallower valence band energies and require an HTM like PEDOT:PSS.

Additionally, PTAA is highly phobic to the perovskite ink precursors, which typically means an interfacial layer or post-deposition modification with UV and ozone is required to deposit a satisfactory absorber layer. Thus, HTMs like PTAA require an additional post-deposition process to improve the wettability of the HTMs to the perovskite inks. To achieve pinhole-free films and increased interfacial affinity between current HTMs and a perovskite solution, the addition of poly(9,9-bis(3′-(N,N-dimethyl)-N-ethylammoinium-propyl-2,7-fluorene)-alt-2,7-(9,9-dioctylfluorene))dibromide (PFN-Br) is required, which is a high-cost additive necessary for many perovskite devices containing the (poly)arylamine moiety and has been suggested to negatively affect overall cell efficiency.

HTMs are an integral component of many diode devices such as solar (e.g., PSCs), OLED, photodetectors, and lasers to name a few. Current HTM lack in the ability to fulfill properties required for these applications such as high glass transition temperatures (T_{g}, above 150° C.), tunable energy levels (i.e., HOMO, LUMO) to match adjacent layers in the device, passivation to address defects at the HTM-perovskite interface, and wettability to allow for ohmic contact of adjacent layers in the device.

There is thus a need in the art for HTMs that can not only be easily tuned for different perovskites, but that can also be easily processed (e.g., solution-processed) with high perovskite ink affinity while demonstrating high performance properties required for HTMs for use in PSCs.

### SUMMARY

Embodiments and configurations of the present disclosure can address these and other needs.

In aspects of the present disclosure, a hole transport polymer (i.e. a hole-transport materials (HTM)), comprises about 0.5 mol % to about 50 mol % of one or more wettable monomers comprising a polycyclic aromatic moiety; and a second monomer comprising an aromatic amine.

In embodiments, the one or more wettable monomers comprise at least one oligooxy group and an alkyl side chain comprising four or fewer carbon atoms.

In embodiments, the at least one oligooxy group is a methoxyethoxy(ethyl) group.

In embodiments, the aromatic amine moiety comprises at least one of a fluorene monomer and a carbazole monomer.

In embodiments, the aromatic amine moiety comprises at least one of an amide group, an alkyl group, a phosphine group, an oligoalkyl group, an oligooxy group, an amine group, and a halogen.

In embodiments, the fluorene monomer is selected from the group comprising dimethylfluorene, dihexylfluorene, dimethylaminopropylfluorene, and dibromofluorene.

In embodiments, the carbazole monomer is selected from the group comprising dibromocarbazole.

In embodiments, the one or more wettable monomers comprises at least one wettable dialkylfluorene monomer and a second wettable fluorene monomer, the second wettable fluorene monomer having a side chain comprising at least one of an amide group, a phosphine group, an oligoalkyl group, a halogen, and an amine group.

In embodiments, the second wettable fluorene monomer is a dimethylaminopropylfluorene monomer.

In embodiments, the aromatic amine comprises aniline or a derivative thereof.

In embodiments, the hole transport polymer further comprises one or more second aromatic amine moieties selected from the group comprising carbazoles, derivatives of carbazoles, fluorenes, derivatives of fluorenes, and combinations thereof.

In embodiments, the hole transport polymer of claim 1 has a decomposition temperature of greater than about 350° C.

In embodiments, the hole transport polymer has a decomposition temperature greater than about 390° C.

In embodiments, the hole transport polymer has a glass transition temperature greater than about 100° C.

In embodiments, the hole transport polymer has a highest occupied molecular orbital (HOMO) energy of about −5.4 eV to about −4.9 eV.

In embodiments, the hole transport polymer has a lowest unoccupied molecular orbital (LUMO) energy of about −2.5 eV to about −2.0 eV.

In embodiments, the hole transport polymer has a water contact angle greater than about 80 degrees.

In embodiments, the second monomer is hydrophobic.

In embodiments, the hole transport polymer is synthesized by a Buchwald-Hartwig cross coupling reaction or an Ullmann reaction.

A fluorene-containing moiety of the hole transport polymer comprising a long alkyl chain may increase solubility of the hole transport polymer. A fluorene-containing moiety comprising a short alkyl chain may increase the glass transition temperature (T_{g}) and improve wettability of the hole transport polymer. A carbazole-containing monomers comprising a long alkyl chain may increase solubility of the hole transport polymer. A carbazole-containing monomer comprising a short alkyl chain may increase the T_{g} and improve wettability of the hole transport polymer.

In embodiments, the one or more wettable monomers are copolymerized with the second monomer comprising the aromatic amine in any ratio to prepare and tune (i.e., adjust) the hole transport polymer with desired properties.

In embodiments, a quantity of the aromatic moiety in the hole transport polymer is adjusted to achieve a desired highest occupied molecular orbital (HOMO), T_{g}, solubility, wettability, or a combination thereof.

In aspects of the present disclosure, a method of manufacturing a perovskite solar cell (PCS) comprises polymerizing a first quantity of one or more wettable monomers comprising at least one carbazole-containing or fluorene-containing moiety with a second quantity of a monomer comprising an aromatic amine to form a wettable copolymeric HTM; and applying a perovskite solution to the wettable copolymeric HTM.

In embodiments, the applying step is carried out without first applying an interfacial wetting additive to the wettable copolymeric HTM.

In embodiments, in the applying step, the perovskite solution completely wets the HTM to produce a continuous perovskite layer with no defects.

In aspects of the present disclosure, a PSC comprises a perovskite layer; and a polymeric HTM, comprising a copolymer of (i) one or more wettable monomers comprising at least one carbazole-containing or fluorene-containing moiety and (ii) a monomer comprising an aromatic amine.

In embodiments, a decomposition temperature of the polymeric HTM is higher than an operating temperature of the PSC.

In embodiments, a decomposition temperature of the polymeric HTM is at least 100° C. higher than an operating temperature of the PSC.

In embodiments, a HOMO energy of the polymeric HTM is about equal to a valence band energy of the perovskite layer.

In aspects of the present disclosure, a method of making the hole transport polymer comprises any of the above embodiments.

In aspects of the present disclosure, a perovskite cell is prepared by polymerizing a first quantity of one or more wettable monomers comprising at least one carbazole-containing or fluorene-containing moiety with a second quantity of a monomer comprising an aromatic amine to form a wettable copolymeric HTM; and applying a perovskite solution to the wettable copolymeric HTM.

The compositions, devices, and methods of the present disclosure can have several advantages. One possible advantage of the compositions, devices, and methods is that one or more properties of a polymer suitable as a HTM can be adjusted to improve the properties of the HTM polymer for use in a PCS, for example. The present disclosure is directed to the design, synthesis, characterization, and purification of polymeric transport materials (HTMs) with desirable properties such as solution processability, energy level tuning (i.e., adjusting), advantageous thermal properties, tunable (i.e., adjustable) wettability (i.e., hydrophilicity), perovskite defect passivation, among others. In some implementations, the synthesis of such polymer transport materials may be implemented via relatively simple and inexpensive production processes.

In one aspect of the present disclosure, an HTM may be synthesized that demonstrates a wettable capability while maintaining compatibility with the perovskite layer and desired properties of an HTM layer (e.g., energy level, thermal properties, hydrophobicity). The capability of the HTM to be wettable is advantageous because the wettable HTM may demonstrate improved interfacial affinity for a perovskite solution. Such wettable HTMs may eliminate the need for additives such as PFN-Br, which may result in a simplified and cost-effective PSC manufacturing process as compared to processes that utilize non-wettable HTMs that require additives such as PFN-Br and the like. In aspects of the present disclosure, a quantity of one or more wettable monomers may be incorporated into polymers suitable for use as HTMs. In some embodiments, only small quantities of the one or more wettable monomers are required to achieve a desired wettability of the resulting HTM. A wettable HTM may demonstrate increased hydrophilicity, which may result in better perovskite ink affinity and processability. The incorporation of wettable HTMs improves the feasibility of fabricating perovskite devices while reducing the overall cost and improving upon efficiencies observed with other HTMs. Additionally, the wettable HTMs are produced via a one-pot synthesis, thereby also improving the efficiency of the HTM and thus a PSC comprising the wettable HTM. The wettable HTMs described herein may advantageously result in a uniform, pinhole-free perovskite film.

In one aspect of the present disclosure, polymers suitable as HTMs are modified to achieve desired thermal and/or wettability properties. For example, copolymer variants of a fluorene and aniline-comprising polymer (FlAn), such as FlAnS, are described. In some implementations, a 9,9-dihexylfluorene unit of a FlAn polymer is at partially or wholly replaced with dimethylfluorene in various ratios to provide a controllable glass transition temperature (T_{g}) with no loss of performance or significant changes in electronic properties of the HTM polymer. In some implementations, a third fluorene-based monomer may be incorporated to achieve an HTM terpolymer further improved wettability, which may allow for direct deposition of the active perovskite layer onto the HTM terpolymer.

As described herein, in one aspect of the present disclosure, a wettable monomer of an HTM (e.g., a wettable fluorene and/or carbazole monomer) may comprise alkyl monomers (e.g., dimethyl) which may result in several advantages. For example, dimethyl monomers may be used in an HTM polymer instead of dihexyl monomers which may lead to improved wettability as dimethyl monomers may reduce “greasy” alkyl chains. Another advantage is that the dimethyl monomers may reduce flexible alkyl chains in the HTM which may increase increases the T_{g} of the HTM.

These and other advantages will be apparent from the disclosure contained herein.

While specific embodiments and applications have been illustrated and described, the present disclosure is not limited to the precise configuration and components described herein. Various modifications, changes, and variations which will be apparent to those skilled in the art may be made in the arrangement, operation, and details of the methods and systems disclosed herein without departing from the spirit and scope of the overall disclosure.

As used herein, unless otherwise specified, the terms “about,” “approximately,” etc., when used in relation to numerical limitations or ranges, mean that the recited limitation or range may vary by up to 10%. By way of non-limiting example, “about 750” can mean as little as 675 or as much as 825, or any value therebetween. When used in relation to ratios or relationships between two or more numerical limitations or ranges, the terms “about,” “approximately,” etc. mean that each of the limitations or ranges may vary by up to 10%; by way of non-limiting example, a statement that two quantities are “approximately equal” can mean that a ratio between the two quantities is as little as 0.9:1.1 or as much as 1.1:0.9 (or any value therebetween), and a statement that a four-way ratio is “about 5:3:1:1” can mean that the first number in the ratio can be any value of at least 4.5 and no more than 5.5, the second number in the ratio can be any value of at least 2.7 and no more than 3.3, and so on.

The embodiments and configurations described herein are neither complete nor exhaustive. As will be appreciated, other embodiments are possible utilizing, alone or in combination, one or more of the features set forth above or described in detail below.

### BRIEF DESCRIPTION OF THE DRAWINGS

The accompanying drawings are incorporated into and form a part of the specification to illustrate several examples of the present disclosure. These drawings, together with the description, explain the principles of the disclosure. The drawings simply illustrate preferred and alternative examples of how the disclosure can be made and used and are not to be construed as limiting the disclosure to only the illustrated and described examples. Further features and advantages will become apparent from the following, more detailed, description of the various aspects, embodiments, and configurations of the disclosure, as illustrated by the drawings referenced below.

FIG. 1 illustrates a schematic related to the selection of a hole transport material (HTM) for use in a perovskite solar cell (PSC), according to embodiments of the present disclosure.

FIG. 2 illustrates a Tauc plot for determining the optical bandgap energy of polymer (CzMee10) disclosed herein, according to embodiments of the present disclosure.

FIG. 3 illustrates a plot comprising the thermal gravimetric analysis (TGA) of polymer HTM (CzMee10) with 5 wt. % decomposition indicated, according to embodiments of the present disclosure.

FIG. 4 depicts a plot of differential scanning calorimetry (DSC) of an HTM (CzMee10) disclosed herein, according to embodiments of the present disclosure.

FIG. 5 depicts a plot of water contact angles of HTMs, according to embodiments of the present disclosure.

FIGS. 6A and 6B depict PSCs prepared with HTMs of the present disclosure.

FIG. 7A depicts a plot of mass percent (%) loss of copolymers disclosed herein as temperatures increase, according to embodiments of the present disclosure.

FIG. 7B depicts a plot of % alkyl content versus glass transition temperature (T_{g}) of HTM polymers prepared according to embodiments of the present disclosure.

FIG. 8 depicts J-V curves for devices prepared with HTM polymers, according to embodiments of the present disclosure.

### DETAILED DESCRIPTION

Unless defined otherwise, all technical and scientific terms used herein have the same meaning as is commonly understood by one of ordinary skill in the art. All patents, applications, published applications, and other publications to which reference is made herein are incorporated by reference in their entirety. If there is a plurality of definitions for a term herein, the definition provided in the Summary prevails unless otherwise stated.

As used herein, “wettability” refers to the tendency of one fluid to spread on or adhere to a solid surface in the presence of other immiscible fluids. A wettable substance used herein is soluble or receptive to moisture.

As used herein, “solubility” refers to the ability of a solid, liquid, or gaseous chemical substance (referred to as the solute) to dissolve in solvent (usually a liquid) and form a solution and is often expressed as the mass of solute per volume (g/L) or mass of solute per mass of solvent (g/g), or as the moles of solute per volume (mol/L).

As used herein, “oligoxy” refers to any side chain that comprises at least one oxygen atom and between one and nine carbon atoms. Nonlimiting examples of an oligoxy group include carboxylic acid groups, sulfonic acid groups, phosphonic acid groups, alcohol groups, and ether groups. A more particular example of an oligooxy group is an ether of the form —(—OCH₂CH₂—)ₙ—OCH₃ where n=0 to 4.

As used herein, “oligoalkyl” refers to an alkyl chain comprising one to nine carbon atoms.

As used herein, “long (or longer) alkyl chains” refers to an alkyl functional group comprising five or more carbon atoms, including but not limited to pentyl, hexyl, 2-ethylhexyl, and octyl.

As used herein, “short (or shorter) alkyl chains” refers to an alkyl functional group comprising up to four carbon atoms, including but not limited to methyl, ethyl, propyl, and butyl.

For purposes of further disclosure and to comply with applicable written description and enablement requirements, the following references generally relate to compositions and methods for the manufacture of HTMs for use in perovskite solar cells (PSCs) and are hereby incorporated by reference in their entireties:
Astridge, D. D.; Hoffman, J. B.; Zhang, F.; Park, S. Y.; Zhu, K.; Sellinger, A. Polymer Hole Transport Materials for Perovskite Solar Cells via Buchwald-Hartwig Amination. ACS Applied Polymer Materials 2021. DOI: 10.1021/acsapm.1c00891.
Hoffman, J. B.; Astridge, D. D.; Park, S. Y.; Zhang, F.; Yang, M.; Moore, D. T.; Harvey, S. P.; Zhu, K.; Sellinger, A. Polymer Hole Transport Material Functional Group Tuning for Improved Perovskite Solar Cell Performance. ACS Applied Energy Materials 2022, 5 (7), 8601-8610. DOI: 10.1021/acsaem.2c01057.
Wang, J.; Yu, Z.; Astridge, D. D.; Ni, Z.; Zhao, L.; Chen, B.; Wang, M.; Zhou, Y.; Yang, G.; Dai, X.; et al. Carbazole-Based Hole Transport Polymer for Methylammonium-Free Tin-Lead Perovskite Solar Cells with Enhanced Efficiency and Stability. ACS Energy Letters 2022, 3353-3361. DOI: 10.1021/acsenergylett.2c01578.
Zhang, L.; Liu, C.; Wang, X.; Tian, Y.; Jen, A. K. Y.; Xu, B. Side-Chain Engineering on Dopant-Free Hole-Transporting Polymers toward Highly Efficient Perovskite Solar Cells (20.19%). Advanced Functional Materials 2019, 29 (39), 1904856. DOI: 10.1002/adfm.201904856.
Tang, C. G.; Ang, M. C. Y.; Choo, K.-K.; Keerthi, V.; Tan, J.-K.; Syafiqah, M. N.; Kugler, T.; Burroughes, J. H.; Png, R.-Q.; Chua, L.-L.; et al. Doped polymer semiconductors with ultrahigh and ultralow work functions for ohmic contacts. Nature 2016, 539 (7630), 536-540. DOI: 10.1038/nature20133.

Embodiments of the present disclosure are generally related to novel compositions of hole transport materials (HTMs). Embodiments of the present disclosure also include methods of producing the HTMs, and a device and methods of manufacturing the device, such as a perovskite solar cell (PSC), comprising the HTM. The compositions, devices, and methods of the present disclosure exhibit advantageous efficiency and cost effectiveness compared to prior art compositions, devices and methods.

A significant advantage of the present disclosure is that various compositions of HTMs can be synthesized to achieve desired properties based on their respective end uses. The compositions may include one or more monomers selected from the group comprising polycyclic aromatic moieties, aromatic amines (e.g., primary amines, di-secondary amines), aryls (e.g., polyarylamine), alkyl chains of any length (i.e., short alkyl chains such as methyl and ethyl or long alkyl chains), oligooxy groups, phenyl groups, oligoalkyl group, amines, phosphine groups, amide groups, etc.

The combination and amounts of the monomers used to synthesize an HTM may be based on the desired properties of the HTM, which may be based on the properties of one or more elements of a device the HTM is to be used for. In embodiments of the present disclosure, the energy levels of the HTM (e.g., highest occupied molecular orbital (HOMO), least unoccupied molecular orbital (LUMO)) may be tuned based on the band gap and/or band edge energies of layers adjacent to the HTM being used in a PSC (e.g., the perovskite layer). In embodiments, the hydrophilicity (i.e., wettability) of the HTM may be tuned to improve the affinity of the HTM to a perovskite layer and/or transparent conductive oxide (TCO) layer which may eliminate the need for interfacial additives, such as PFN-BR. In embodiments, the glass transition temperature (T_{g}) of the HTM may be tuned to ensure the HTM can withstand processing and/or operating conditions desired for the PSC in which the HTM is incorporated.

The incorporation of tuned HTMs based on application improves the feasibility of fabricating perovskite devices while reducing the overall cost and improving upon efficiencies seen with other HTMs. In some embodiments, the improved wettability of HTMs for implementation into a PSC may lead to the ability to manufacturing a PSC without the needed for high-cost interfacial additives, such as PFN-Br, thereby further reducing processing steps and costs.

In some embodiments, aromatic amines (alone or together with other functional groups) may be incorporated into an HTM to serve as either an electron withdrawing group meant to deepen the HOMO (more negative, farther from vacuum) or an electron donating group to produce a shallower HOMO (less negative, closer to vacuum). Aromatic amines may also be utilized in a polymer to adjust T_{g}, solubility, and wettability. Longer alkyl chains (e.g., pentyl, hexyl, 2-ethylhexyl, octyl, etc.) may be incorporated into the HTM to increase solubility of the polymer. Shorter alkyl chains (i.e., methyl and/or ethyl) may be incorporated into the HTM for increasing T_{g} and improving wettability. Other wettable monomers comprising oligoxy groups, amines, etc. may be incorporated into the HTM to increase wettability and the affinity of the HTM to a perovskite layer and/or TCO layer of a PSC (e.g., improving perovskite ink affinity). Other monomers including but not limited to hydrocarbons, amides, and halogens may also be used in specific quantities and configuration to tune the properties of the HTM. The monomers used to synthesize an HTM are balanced carefully to provide polymers with specifically tuned properties.

In embodiments of the present disclosure, an HTM may be synthesized to include one or more polycyclic aromatic moieties. The one or more polycyclic aromatic moieties may include a carbazole moiety and a fluorene moiety. The one or more polycyclic aromatic moieties may additionally include one or more side chains selected from the group comprising amides, phosphines, oligoalkyls, oligoxys, halogens, and amines. Non-limiting examples of a carbazole moiety may include a halogen-comprising carbazole, such as 2,7-dibromocarbazole. Non-limiting examples of a fluorene moiety may include a halogen-comprising fluorene such as 2,7-dibromofluorene, or a alkyl-comprising fluorene such as dihexylfluorene, dimethylfluorene and bis-dimethylaminopropylfluorene. It should be expressly understood that embodiments of the present disclosure are not so limited and any polycyclic aromatic moiety may be used that achieves desired properties of a resulting HTM.

In some embodiments, the HTM may comprise a copolymer of one or more of the polycyclic aromatic moieties. In a non-limiting example, the copolymer may include dihexylfluorene and dimethylfluorene. Polycyclic aromatic monomers may be combined in a copolymer in any ratio. By way of example, dihexylfluorene and dimethylfluorene may be combined in a ratio of 90:10, 80:20, 70:30, 60:40:50:50, and vice versa.

In some embodiments, the HTM may comprise a terpolymer of one or more of the polycyclic aromatic moieties. In a non-limiting example, the copolymer may include dihexylfluorene, dimethylfluorene, and bis-dimethylaminopropylfluorene. Polycyclic aromatic monomers may be combined in a terpolymer in any ratio.

In embodiments, HTMs of the present disclosure comprise one or more aromatic amines. Non-limiting examples of aromatic amines includes primary aromatic amines, such as aniline, and di-secondary aromatic amines such as diphenylamine.

An HTM of the present disclosure may include one or more monomers selected from the group comprising alkyl chains of any length, oligooxy groups (e.g., alcohol groups, ether groups, carboxylic acid groups, sulfonic acid groups, phosphonic acid groups), halogens, amides, phosphines, etc. In a non-limiting example, the one or more monomers may be wettable, such as methoxyethoxy(ethyl). In a non-limiting example, the one or more alkyl chains may include a combination of alkyl chains (e.g., dihexyl, ethylhexyl).

In embodiments of the present disclosure, one or more of the monomers disclosed herein (e.g., polycyclic aromatic monomers, aromatic amines, aryls, alkyl chains of any length, oligooxy groups, amines, etc.) may be combined to form a wettable monomer for use in the synthesis of an HTM polymer. The wettable monomer derivatives may be copolymerized with one or more hydrophobic monomers resulting in polymers with improved processability and performance for use in PSCs.

In a non-limiting example, a polycyclic aromatic moiety may be combined with one or more alkyl groups. For example, a fluorene-comprising moiety may be combined with a long alkyl chain for improved solubility or a short alkyl chain for improved wettability and to achieve an increased T_{g}, or a combination thereof. In another example, a carbazole-comprising moiety may be combined with a long alkyl chain for improved solubility or a short alkyl chain for improved wettability and to achieve an increased T_{g} or a combination thereof.

Additionally or alternatively, a polycyclic aromatic moiety may by combined with one or more wettable monomers, such as an oligoxy group. For example, a fluorene-comprising moiety may be combined with methoxyethoxy(ethyl) group for use in synthesizing an HTM of the present disclosure. In another example, a carbazole-comprising moiety may be combined with a methoxyethoxy(ethyl) group for use in synthesizing an HTM of the present disclosure.

In embodiments, the one or more monomers may attach to the one or more polycyclic aromatic moieties as a pendant group. In a non-limiting example, an oligooxy group, such as methoxyethoxy(ethyl), may be attached to the 9-position of 2,7-dibromocarbazole or 2,7-dibromofluorene molecules.

An HTM polymer of the present disclosure may be synthesized via a “one-pot” synthesis. The HTM may be synthesized by a Buchwald-Hartwig cross coupling reaction or an Ullmann reaction.

In embodiments, an HTM of the present disclosure may be synthesized to include between about 0.5 and 50 mol %, or more particularly between about 2 and 40 mol %, or more particularly between about 3 and 30 mol %, and more particularly between about 4 and 20 mol %, or even more particularly between about 5 and 15 mol % of a wettable monomer comprising a polycyclic aromatic moiety. Stated differently, an HTM may comprise up to about 50 mol % of a wettable monomer comprising a polycyclic aromatic moiety.

The HTM polymer may then be implemented in the described application, such as a PSC. In some embodiments, the HTM polymer may be applied between a perovskite layer and a TCO layer of the PSC. Based at least in part on the properties of HTM polymer, the HTM polymer may be applied to the perovskite layer, the TCO layer, or both without the need for an interfacial wetting layer, such as PFN-BR.

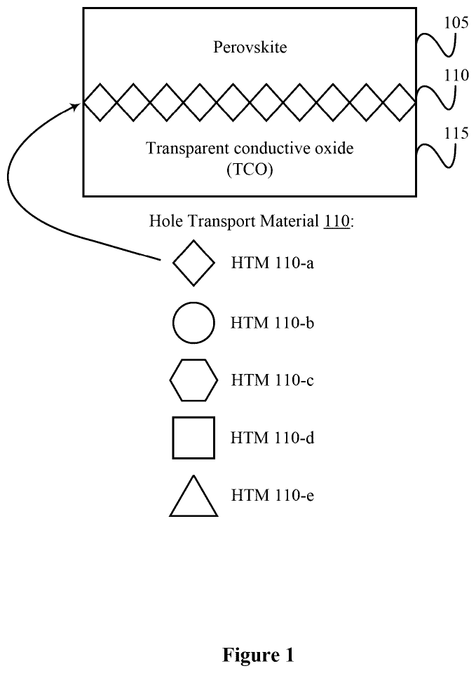

FIG. 1 illustrates a schematic related to the selection of an HTM for use in a PSC, according to embodiments of the present disclosure. A PSC may comprise at least a perovskite layer 105, an HTM layer 110, and a transparent conductive oxide (TCO) layer 115. It should be understood that FIG. 1 is a simplified illustration of a PSC and may omit other layers typically found in a PSC and as such, PSCs manufactured according to embodiments of the present disclosure may include additional layers.

As described herein, an HTM polymer may be tuned to achieve properties suitable for use in a PSC. For example, the desired properties of the HTM polymer may be based on one or more properties of the perovskite 105 and/or TCO 115 layers of the PSC, such as wettability, solubility, energy, T_{g}, Td, passivation, etc. By way of a simplified explanation, an HTM 110-a may be selected from a set of HTMs (e.g., HTMs 110-a to 110-e) based on the properties of HTM 110-a being compatible with the perovskite 105 and the TCO 115. Alternatively, HTM 110-a may be synthesized specifically for use in a PSC comprising the perovskite 105 and TCO 115 based at least in part on tuning or adjusting the individual monomers and/or the combination of monomers included in the HTM 110-a. It should be expressly understood that any number of HTM polymers may be synthesized and the present disclosure is not limited to five, as depicted in FIG. 1.

Glass transition temperature (T_{g}) is the temperature at which an amorphous polymer changes from a hard/glassy state to a soft/leathery state, or vice versa and may indicate the temperature range over which a polymer will be considered stable and retain its mechanical properties. An HTM of the present disclosure comprises a T_{g} not less than about 100° C., or more typically greater than about 105° C., or more typically greater than about 110° C., or even more typically greater than about 115° C. Stated differently, an HTM of the present disclosure comprises a T_{g} between about 100° C. and 250° C., or more typically between about 105° C. and 240° C., or more typically between about 110° C. and 230° C., or even more typically between about 115° C. and 220° C.

Decomposition temperature (Td) is the temperature at which a substance begins to chemically decompose and can be used as an indicator of the performance of a polymer for use in certain applications. For example, a polymer for use in a PSC needs to have a Td not lower than temperatures reached during manufacturing and use of the PSC. For the purposes of the present disclosure, Td is determined at the point at which a weight of a substance was reduce by about 5 wt. %. An HTM of the present disclosure comprises a Td not less than about 350° C., or more typically greater than about 360° C., or more typically greater than about 370° C., or more typically greater than about 380° C., or more typically greater than about 390° C., or even more typically greater than about 400° C., which is well above typical operating conditions of PSCs. Stated differently, an HTM of the present disclosure may comprise a Td between about 350° C. and 500° C., or more typically between about 360° C. and 490° C., or more typically between about 370° C. and 480° C., or more typically between about 380° C. and 470° C., or more typically between about 390° C. and 460° C., or even more typically between about 400° C. and 450° C.

Water contact angle refers to the angle between a liquid surface and a solid surface where the surfaces meet. Generally, if the water contact angle is less than 90°, the solid surface is considered hydrophilic and if the water contact angle is greater than 90°, the solid surface is considered hydrophobic. While water contact angle is not a direct representation of the polymer's affinity for perovskite ink, it can be used as an indicator. An HTM of the present disclosure exhibits a water contact angle between about 80° and 100°, and more typically between about 850 and 95°. Stated differently, an HTM of the present disclosure exhibits a water contact angle not less than 800.

In embodiments of the present disclosure, some monomers, such as aromatic amines, can serve as either an electron withdrawing group meant to deepen the HOMO (more negative, farther from vacuum) or an electron donating group to produce a shallower HOMO (less negative, closer to vacuum). By combining one or more of the monomers or pendant groups herein in particular configurations to form an HTM polymer, the HOMO level of the HTM polymer can be tuned over a broad range such that the HTM polymer is compatible with a perovskite layer it will be in contact with. An HTM of the present disclosure comprises a HOMO between about −6 eV and about −4 eV, or more particularly between about −5.7 eV and about −4.5 eV, or even more particularly between about −5.4 eV and about −4.9 eV.

In embodiments, an HTM of the present disclosure comprises a LUMO between about −3 eV and −1.5, or more particularly between about −2.5 eV and −2.0 eV.

The compositions, apparatuses, systems, and methods of the present disclosure have been described with some degree of particularity directed to the exemplary embodiments of the present disclosure. It should be appreciated, however, that modifications or changes may be made to the exemplary embodiments of the present disclosure without departing from the inventive concepts contained herein.

Unless defined otherwise, all technical and scientific terms used herein have the same meaning as is commonly understood by one of ordinary skill in the art. All patents, applications, published applications, and other publications to which reference is made herein are incorporated by reference in their entirety. If there is a plurality of definitions for a term herein, the definition provided in the Summary prevails unless otherwise stated.

In some embodiments, an HTM of the present disclosure may be synthesized with as further described with reference to Example 1 to 14, below. The methods and systems of the present disclosure are further described by way of the following illustrative, non-limiting experimental Examples.

### Example 1

### Synthesis of a Wettable Carbazole-Comprising Monomer, Cz

To synthesize a wettable 2,7-dibromo-9-(2-(2-methoxyethoxy)ethyl)-9H-carbazole (Cz) monomer, a 50 mL Schlenk flask and a stir bar were oven dried at 105° C. and then charged with 2,7-dibromo-9H-carbazole (0.801 g, 2.460 mmol). The flask was then subjected to three vacuum/nitrogen refilling steps. Sodium hydride (in a 60% mineral oil dispersion) (0.1202 g, 5.001 mmol) and 1-bromo-2-(2-methoxyethoxy)ethyl (0.4965 mL, 3.690 mmol) were added to the flask with positive nitrogen flow. 20 mL of anhydrous dimethylformamide (DMF) was added to the flask via a syringe while stirring. The reaction mixture was stirred at room temperature for 12 hours. Thin layer chromatography (TLC) was used to analyze the progression of the reaction. After the reaction was complete per the TLC analysis, deionized water was slowly added in excess. The reaction product was extracted with ethyl acetate. The organic portions of the reaction product were washed with a brine solution and dried with anhydrous magnesium sulfate, filtered, and concentrated via a rotary evaporator. The crude reaction mixture was purified via recrystallization in hexanes and insolated to afford a white solid (96% yield).

The synthesis of a wettable monomer Cz is provided in Equation 1, below.

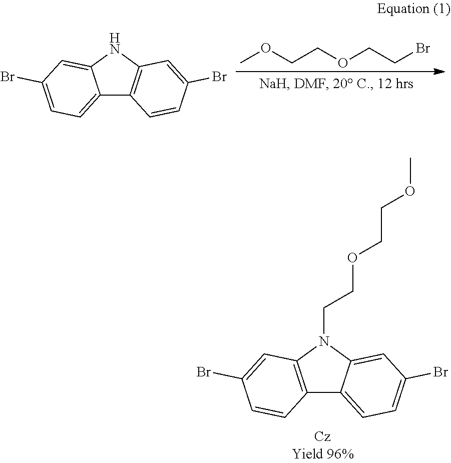

### Example 2

### Synthesis of a Wettable Fluorene-Comprising Monomer, Fl

To synthesize a wettable 2,7-dibromo-9,9-bis(2-(2-methoxyethoxy)ethyl-9H-fluorene (Fl) monomer, a 50 mL Schlenk flask and a stir bar were oven dried at 105° C. and then charged with 2,7-dibromofluorene (0.986 g, 3.043 mmol) and tetrabutylammonium bromide (0.196 g, 0.609 mmol). The flask was then subjected to three vacuum/nitrogen refilling steps. 10 mL of anhydrous toluene and 4 mL of 50% sodium hydroxide were added to the flask via a syringe while stirring. The reaction mixture was heated to 80° C. and stirred for 45 min. 1-bromo-2-(2-methoxyethoxy)ethyl was then added dropwise via syringe to the solution and the solution was stirred for 15 hours. Thin layer chromatography (TLC) was used to analyze the progression of the reaction. After the reaction was complete per the TLC analysis, deionized water was slowly added to the mixture in excess. The reaction product was extracted with methylene chloride. The organic portions of the reaction product were washed with a brine solution and dried with anhydrous magnesium sulfate, filtered and concentrated via rotary evaporator. The crude reaction mixture was purified using a column chromatography (1:1, petroleum ether:ethyl acetate), and concentrated to produce a pale yellow oil (61%).

The synthesis of wettable monomer Fl is provided in Equation 2, below.

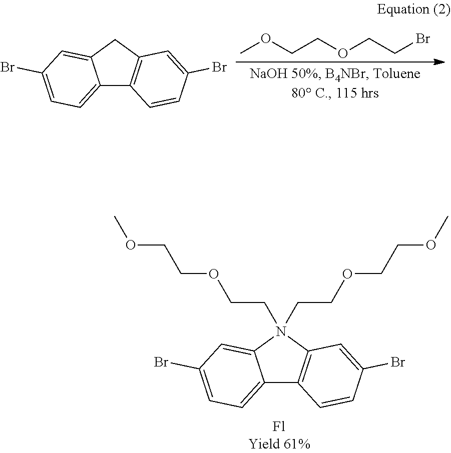

### Example 3

### Synthesis of Wettable Carbazole-Comprising Polymer, CzMee10

To synthesize a wettable polymer of the present disclosure, CzMee10, a 50 mL Schlenk flask and stir bar were oven dried at 105° C. and then charged with 2,7-dibromo-9-(2-ethylhexyl)carbazole (0.5399 g, 1.235 mmol), 2,7-dibromo-9-(2-(2-methoxyethoxy)ethyl)-9H-carbazole (of Example 1) (0.0586 g, 0.137 mmol) and sodium tert-butoxide (0.3950 g, 4.110 mmol). The flask was then subjected to three vacuum/nitrogen refilling steps. Aniline (0.1250 mL, 1.372 mmol) was added to the flask with positive nitrogen flow via a micropipette. 10 mL of Anhydrous toluene was added to the flask via a syringe while stirring. Bis(tri-tert-butylphosphine)palladium(0) (0.0280 g, 0.054 mmol) was added to the reaction flask with positive nitrogen flow. The solution was heated to 80° C. for 24 hours.

Once complete, bromobenzene (0.0075 mL, 0.061 mmol) was added to the flask via micropipette with positive nitrogen flow. The reaction was allowed to proceed for another hour. At the end of the hour, diphenylamine (0.0205 g, 0.122 mmol) was added to the flask to complete the polymer chain termination.

An hour after the diphenylamine addition, the heat was turned off and the solution was allowed to cool to room temperature. Once cooled, 15 mL of tetrahydrofuran (THF) was added to the mixture and left to stir for 15 min. The reaction mixture was then precipitated dropwise into 250 mL of stirring methanol and left to stir for 15 min. The precipitate was collected using vacuum filtration and dried in a vacuum oven at 60° C. for 16 hours. The dried product was then redissolved in 5 mL of THE which was placed in a short silica plug and flushed solvent to remove the palladium catalyst. The remaining product was rotary evaporated to produce a yellow/green solid (95% yield).

The synthesis of a wettable polymer CzMee10 is provided in Equation 3, below.

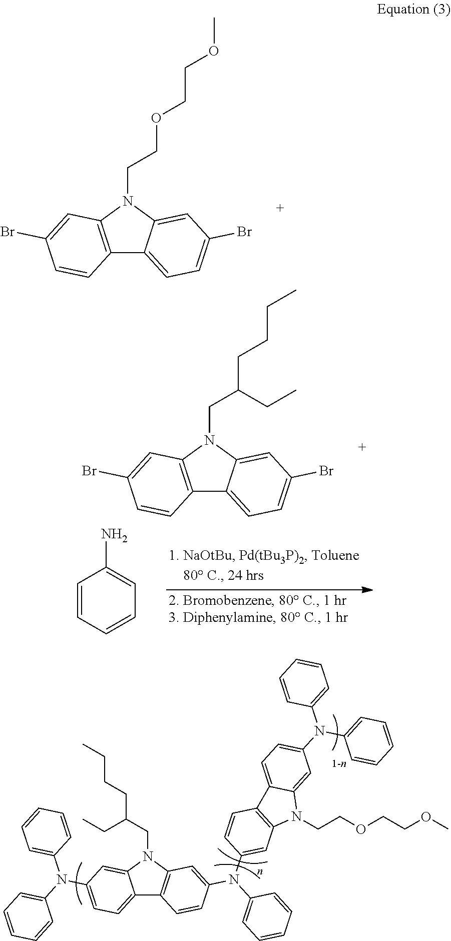

### Example 4

### Synthesis of Wettable Carbazole-Comprising Polymer, CzMee5

A wettable polymer of the present disclosure, CzMee5, was synthesized via the same procedures used in Example 3 to synthesize CzMee10 utilizing 2,7-dibromo-9-(2-ethylhexyl)carbazole (0.5654 g, 1.293 mmol) and 2,7-dibromo-9-(2-(2-methoxyethoxy)ethyl)-9H-carbazole (0.0263 g, 0.069 mmol).

The same procedure used for the purification of CzMee10 was also used to purify the CzMee5 of present Example 4, producing a yellow solid (88% yield).

The synthesis of a wettable polymer CzMee5 is provided in Equation 4, below.

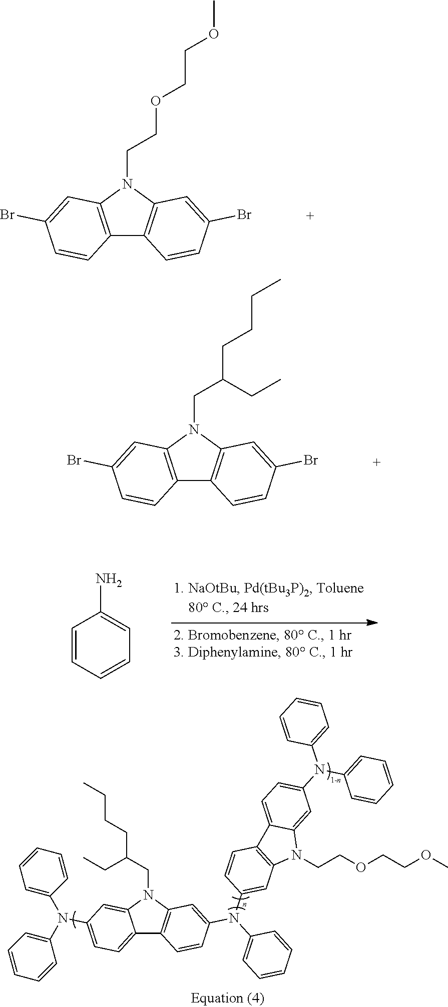

### Example 5

### Synthesis of Wettable Fluorene-Comprising Polymer, FlMee10

A wettable polymer of the present disclosure, FlMee10, was synthesized using the same procedures as the synthesis of CzMee10 of Example 3, with 2,7-dibromo-9-dihexyl-fluorene (0.530 g, 1.076 mmol) and 2,7-dibromo-9,9-bis(2-(2-methoxyethoxy)ethyl-9H-fluorene (0.070 g, 0.132 mmol).

The same procedure used for the purification of CzMee10 in Example 3 was also used to purify FlMee10 of present Example 5, producing a yellow solid (89% yield).

The synthesis of a wettable polymer FlMee10 is provided in Equation 5, below.

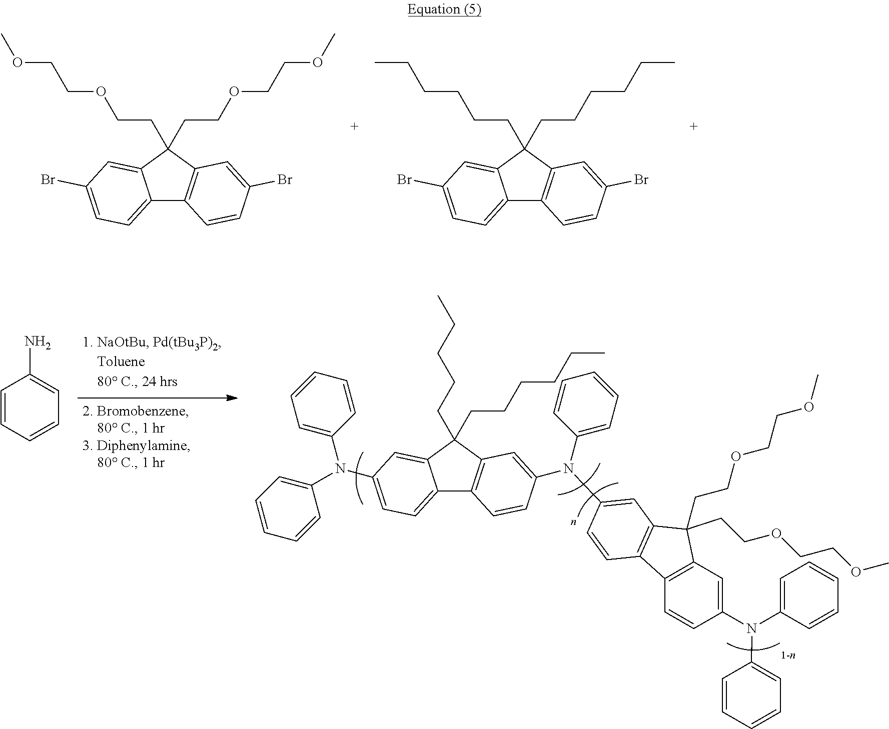

### Example 6

### Structural Analysis of Wettable Compounds

Wettable monomers were incorporated into polymers CzMee10, CzMee5 and FlMee10 at 5 and 10 mol %. ¹H-NMR was used to verify that the intended amount of wettable monomer units were incorporated into the polymers. For example, with 10 mol % incorporation of Mee into CzMee10, the terminal methyl protons were integrated to show a 1:10 ratio, indicating that the synthesized polymer was composed of 10 mol % Mee and 90 mol % Cz monomers.

### Example 7

### Physical Analysis of Wettable Compounds—Optical Band Gap

P-I-N devices are fabricated so that light can pass through multiple layers prior to reaching the active perovskite layer where it is eventually absorbed. These layers include the glass protective layer, anode and HTM. To prevent parasitic absorption from the HTM layer, materials that absorb minimal amounts of the solar spectrum are preferred.

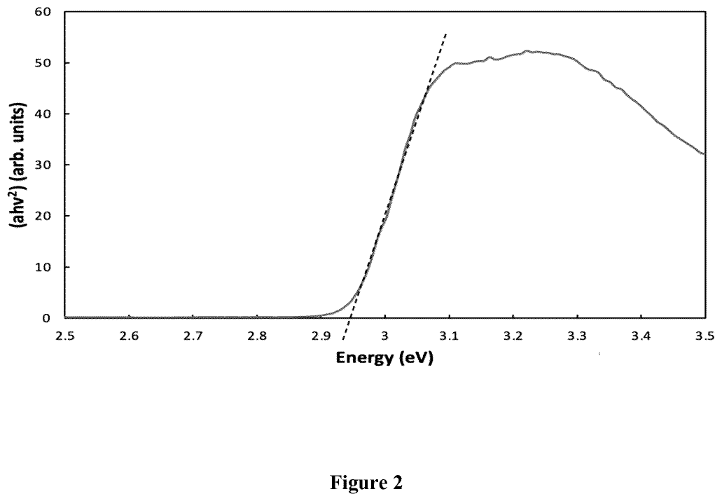

FIG. 2 illustrates a Tauc plot for determining the optical bandgap energy of CzMee10 as disclosed herein, particularly in Example 3. From FIG. 2, the optical band gap was calculated by extrapolating a linear fit from the UV/Vis onset to the x-axis. For CzMee10, the optical band gap was determined from the Tauc plot to be 2.95 eV, which is comparable to PTAA with a optical band gap of 3.07 eV. As such, little parasitic absorption is expected to be observed for CzMee10.

Optical band gap energies for CzMee5 and FlMee10 were determined in the same manner via their respective Tauc plots. CzMee5 and FlMee10 were determined to have optical band gap energies of 2.93 and 2.93 eV, respectively. As such, little parasitic absorption is expected to be observed for CzMee5 and FlMee10.

### Example 8

### Physical Analysis of Wettable Compounds—Energy Orbitals

Along with wide optical band gaps, it is preferable to have materials with orbital energy (i.e., HOMO) levels comparable to the valence band energy of the perovskite active layer. Comparable energy levels between the materials optimizes hole extraction from the active layer to the HTM layer which is one of the factors that contributes to the efficiency of a device. Having a shallow LUMO is also an important factor for a material because it ensures that electron transport is limited from the active layer to the HTM.

To determine the HOMO level of CzMee10, photoelectron spectroscopy in air (PESA) was performed on spun coat thin films (˜12 nm) which produced a value of −5.01 eV. Using this information along with the respective optical bandgaps, the LUMO of CzMee10 was calculated to be −2.09 eV which is comparable to other high performing HTMs. The HOMO and LUMO values for CzMee10 are comparable to those observed for PTAA, as well as CzMee5 and FlMee10, suggesting that CzMee10, CzMee5, and FlMee10 possess the desired properties of a high efficiency P-I-N device, at least compared to PTAA.

### Example 9

### Physical Analysis of Wettable Compounds—Thermal Decomposition Characterization

Thermal characterization of each wettable polymer was evaluated to ensure stability at processing and operating conditions. The decomposition temperatures (Td) of each polymer of the present disclosure were measured at 5 wt. % loss using thermal gravimetric analysis (TGA) and the results are presented in Table 1, below.

TABLE 1
Thermal characterization of wettable and non-wettable HTMs.

| | Wettable Monomer | T_{g} | T_{d} |
|---|---|---|---|
| Polymer | Equivalence (n) | (° C.) | (° C.) |
| CzMee10 | 0.1 | 129.7 | 402.7 |
| CzMee5 | 0.05 | 127.1 | 407.3 |
| FlMee10 | 0.1 | 114.1 | 398.0 |
| CzAn | 0 | 156.0 | 420.0 |
| FlAn | 0 | 116.0 | 409.0 |

As observed from Table 1, each of the wettable polymers had a Td exceeding 390° C., well above the operating temperatures of PSCs.

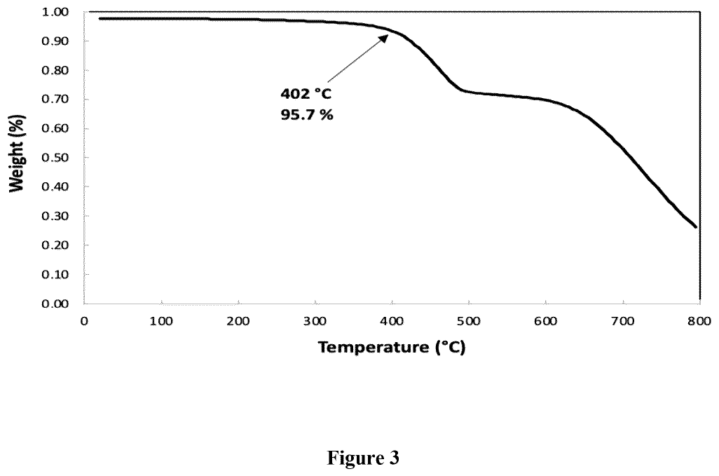

FIG. 3 illustrates a plot comprising the thermal gravimetric analysis (TGA) of CzMee10 HTM with 5 wt. % decomposition indicated. In FIG. 3, the first distinct mass loss observed around 400° C. is the degradation of the ethylhexyl and methoxyethoxy(ethyl) chains at the 9-position of the monomers. This is followed by another step around 650° C. which is the beginning of the polymer backbone degradation, well beyond the operating temperatures of PSCs.

### Example 10

### Physical Analysis of Wettable Compounds—Glass Transition Temperature Characterization

Differential scanning calorimetry (DSC) was conducted to determine the glass transition temperature (T_{g}) of the polymers disclosed herein. From the DSC, it was determined that the wettable polymers ranged about 15° C. in their T_{g} with the lowest being FlMee10 at 114.7° C. and the highest being CzMee10 at 127.9° C.

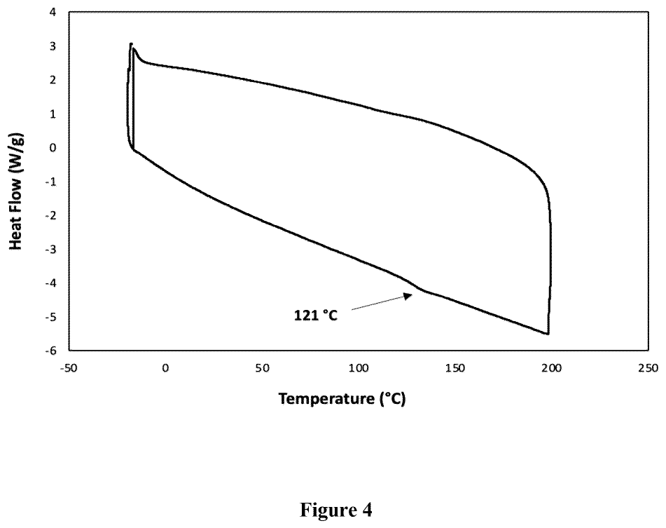

FIG. 4 depicts a plot of differential scanning calorimetry (DSC) of CzMee10 HTM.

The carbazole aryl halide-based polymers (i.e., CzMee10 and CzMee5) each had a slightly higher T_{g} than the fluorene-based analogues (i.e., FlMee10). Without being bound by theory, it is thought that this difference in T_{g} is due to the lower amount of alkyl chains of the carbazole monomer compared to the fluorene monomer. For example, the bulky dihexyl group bonded to the fluorene monomer decreases polymer stacking, leading to lower T_{g} values. In contrast, the ethylhexyl chain on the carbazole monomer allows for tighter packing of the polymer, increasing its T_{g}.

As the wettable monomer incorporation increased from 0 wt. % to 10 wt. %, the T_{g} decreased 26° C. for the carbazole based polymers and only 2° C. for the fluorene-based polymer. While these changes in T_{g} are significant, they should not directly affect device performance or lifetime at normal processing and operating temperatures. Devices with materials that have a T_{g} lower than 100° C. have demonstrated reduced stability and reduced overall lifetime as well as device damage during device processing steps. As such, CzMee10, CzMee5, and FlMee10 are expected to remain stable during device processing, maintain stability, and typical lifespan as compared to a HTM with a T_{g} less than 100° C.

### Example 11

### Physical Analysis of Wettable Compounds—Hydrophilicity

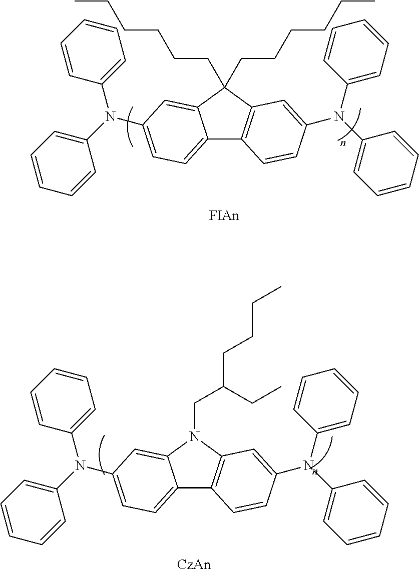

FlAn and CzAn, provided above, comprise no wettable monomer incorporation.

Small amounts of wettable monomer (Cz, Fl, or another compound comprising one or more wettable monomers) were incorporated into the polymers as disclosed herein to increase the wettability of the polymer, compared to their hydrophobic analogue polymers (CzAn and FlAn), above. While the hydrophobic nature of HTMs is crucial in preventing the parasitic degradation of perovskite films, the incorporation of these wettable monomers in small amounts can preserve the parasitic degradation prevention while improving perovskite film deposition. Methoxyethoxy(ethyl) was selected because of its ability to increase the polymer's surface energy and overall affinity for the organic solvents during the perovskite deposition.

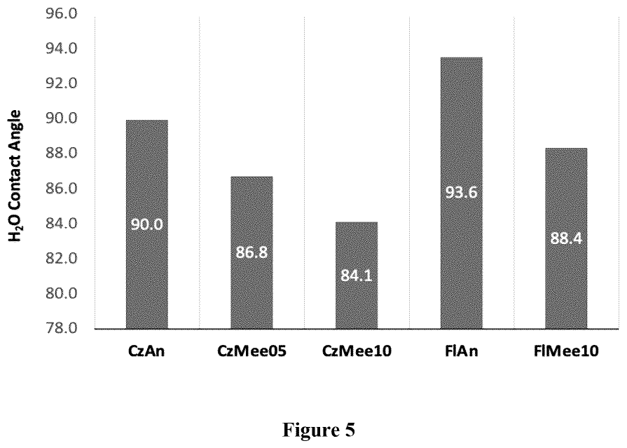

FIG. 5 depicts a plot of water contact angles of HTMs according to the present disclosure. Specifically, FIG. 5 depicts the water contact angles for HTMs with methoxyethoxy(ethyl) versus analogue polymers without methoxyethoxy(ethyl). The water contact angles of the HTMs were determined using a high-resolution goniometer. The data associated with FIG. 5 is provided in Table 2, below.

Hydrophobic surfaces are defined as those which produce a high water contact angle, usually equal to or greater than 90. Through water contact angle measurements, it was observed that the hydrophilic nature of methoxyethoxy(ethyl) chains when compared to ethylhexyl alkyl chains, increased the perovskite ink affinity of polymer CzMee10. From FIG. 5, CzMee5, CzMee10, and FlMee10 are each more hydrophilic (or wettable) than their counterpart polymers comprising ethylhexyl alkyl.

Carbazole based polymers exhibited lower water contact angles than their fluorene analogues which, without being bound by theory, is likely due to the lone pair of electrons on the nitrogen heteroatom as well as a smaller alkyl chain content. A trend can also be observed in FIG. 5; as wettable monomer incorporation increased from 0 mol % to 5 mol % and 10 mol % the contact angle measurements decrease about 3° from each sample respectively. While water contact angle is not a direct representation of the polymer's affinity for perovskite ink, it can be concluded that this trend is comparable to what would be observed with perovskite ink formulations.

TABLE 2
Water contact angle measurements for
wettable and non-wettable HTMs.

| | CzMee10 | CzMee5 | FlMee10 | | |
|---|---|---|---|---|---|
| Water | (10 mol | (5 mol | (10 mol | | |
| Drop | % Cz) | % Cz) | % Fl) | CzAn | FlAn |
| 1 | 84.3 | 87.9 | 88.3 | 90.3 | 93.1 |
| 2 | 83.5 | 87.6 | 88.1 | 90.6 | 94.2 |
| 3 | 84.6 | 84.8 | 88.8 | 89.1 | 93.5 |
| Average | 84.1 ± 0.5 | 86.8 ± 1.4 | 88.4 ± 0.3 | 90.0 ± 0.6 | 93.6 ± 0.5 |

### Example 12

### Performance of Wettable Compounds—Perovskite Ink Affinity

The performance and processing requirements of CzMee10 and CzMee5 were compared to CzAn, the non-wetting polymer analogue. These samples were solution processed into perovskite solar cells using the standard triple-cation perovskite formula (FA_{0.79}MA_{0.16}Cs_{0.5})Pb-(I_{0.84}Br_{0.16})₃ as the active layer.

As expected, CzAn was too hydrophobic to produce a uniform, pinhole-free film of perovskite during the solution-based deposition process and because of this, CzAn required an additional PFN-Br wetting layer.

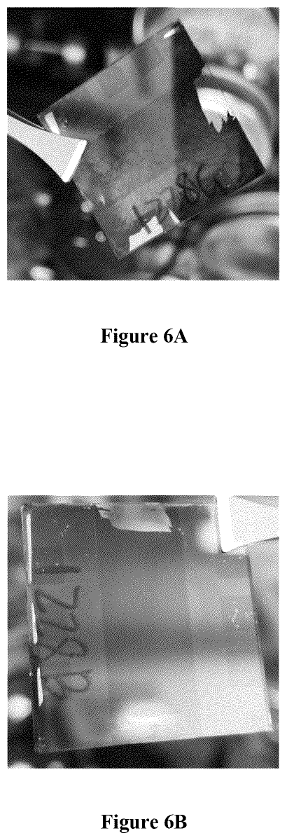

FIG. 6A depicts a perovskite solar cell prepared with CzAn and PFN-Br and FIG. 6B depicts a perovskite solar cell prepared with CzMee10. Taken together, FIGS. 6A and 6B demonstrate the contrast in deposition of the hydrophobic CzAn with PFN-BR versus the wettable CzMee10.

While CzAn required the interfacial wetting layer (with PFN-Br), CzMee10 displayed a higher affinity for the perovskite ink. This produced a uniform, pinhole-free perovskite film as observed above in FIG. 6B. The increased perovskite ink affinity produced by the methoxyethoxy(ethyl) groups was observed in both CzMee10 and CzMee5, indicating that these CzMee10 and CzMee5 surprisingly and unexpectedly eliminate the need for PFN-Br, as well as reduce device manufacturing time, effort and cost associated with perovskite solar cell manufacturing.

### Example 13

### Performance of Wettable Compounds—Perovskite Solar Cell Efficiency

Perovskite solar cells were prepared with CzMee10, CzMee5, and CzAn and PFN-Br. The open circuit voltage (Voc), current density (Jsc), fill factor (FF) and power conversion efficiencies (PCE) were tested for the prepared solar cells and recorded under standard testing conditions. Measurements for the prepared solar cells comprising CzMee10, CzMee5 and CzAn/PFN-Br are shown below in Table 3.

TABLE 3
Parameters of solar cells prepared with
HTMs of the present disclosure.

| | Wettable | | | | | |
|---|---|---|---|---|---|---|
| | Monomer | | | | | |
| | Equivalence | Scan | Voc | Jsc | | PCE |
| Polymer | (n) | Direction | (V) | (mA/cm2) | FF | (%) |
| CzMee10 | 0.10 | Fwd | 0.956 | 22.1 | 0.753 | 15.9 |
| | | Rev | 0.963 | 22.4 | 0.810 | 17.4 |
| CzMee5 | 0.05 | Fwd | 0.961 | 22.0 | 0.722 | 15.3 |
| | | Rev | 0.971 | 22.1 | 0.797 | 17.1 |
| CzAn & | 0 | Fwd | 1.04 | 19.5 | 0.670 | 13.5 |
| PFN-Br | | Rev | 1.04 | 19.6 | 0.723 | 14.8 |

It is noted that the HTMs were not optimized for solution concentration and thickness. It has been shown previously that concentrations of 4 mg/mL of HTM solution and films around 15 nm in thickness are optimal for device performance. The HTMs of Table 4 were solution processed with a concentration of 1 mg/mL which may explain why the PCEs were less than expected. However, in terms of PCE, the devices comprising wettable polymers both outperformed the device with CzAn/PFN-Br.

In embodiments of the present disclosure, an HTM may be synthesized with a polycyclic aromatic moiety and an aromatic amine-comprising moiety. The polycyclic aromatic moiety may include, but is not limited to, a fluorene-comprising moiety (Fl) and/or a carbazole-comprising moiety (Cz). The aromatic amine-comprising moiety may include, but is not limited to, aniline (An), 4-fluoroaniline (AnF), p-anisidine (AnO), 4-(methylthio)aniline (AnS).

The resulting HTM, for example, may be, may include, or be derived from CzAn, CzAnF, CzAnS, and/or CzAnO, though it should be understood that other carbazole and aniline comprising compounds may also be used for use in synthesizing HTMs of the present disclosure.

In another example, the resulting HTM may be, may include, or be derived from FlAn, FlAnF, FlAnS, and/or FlAnO, though it should be understood that other fluorene and aniline comprising compounds may also be used for use in synthesizing HTMs of the present disclosure.

Abbreviations for the HTMs were selected based on the identity of the fluorene or carbazole core (Fl or Cz) from the aryl dihalide, followed by the identity of the functionalized pendant group (An, AnF, AnO, AnS) from the primary amine.

Specific examples related to fluorene and aniline comprising compounds are described below with reference to Examples 14 to 26. In particular, the below experiments are directed to copolymer variants of FlAnS due to the exceptional PCE and stability of FlAnS.

### Example 14

### Synthesis of 3,3′-(2,7-dibromo-9H-fluorene-9,9-diyl)bis(N,N-dimethylpropan-1-amine) monomer

A 250 mL round bottom flask was charged with 2,7-dibromo-9H-fluorene (3.9977 g, 12.34 mmol) and 3-dimethylaminopropyl chloride (5.40 g, 44.4 mmol). Tetrabutylammonium bromide (0.0911 g, 0.283 mmol) was added, and the flask was purged with vacuum and refilled with nitrogen three times. The solids were dissolved in DMSO (50 mL) with stirring at room temperature followed by the addition of 8 mL of sodium hydroxide solution, 50% w/w in deionized water. Upon addition, the mixture was observed to turn cherry red and gelatinous. The temperature was increased to 60° C. and allowed to stir for 1 hour while monitored by thin layer chromatography, whereupon the reaction was cooled to room temperature and quenched by pouring into iced water. The mixture was extracted three times with diethyl ether. The organic layer was washed three times with 10% NaOH solution and three times with saturated sodium chloride solution, followed by drying over MgSO4. The organic solvents were removed by rotary evaporation to afford a pink oil. The crude product was then purified by column chromatography (4:1 hexanes:ethyl acetate on silica) followed by recrystallization in hexanes to obtain a fine white powder (4.45 g, 73% yield).

### Example 15

### Polymer Synthesis

All polymers variants followed the same general procedure, outlined herein. To an oven dried Schlenk flask sodium tert-butoxide (3 equivalents) and appropriate dibromofluorenes (varying) were added, followed by evacuation by three vacuum and nitrogen refills. Anhydrous toluene was added to the flask via syringe with stirring. 4-(methylthio)aniline (1 equivalent relative to fluorenes) was added to the flask via autopipette with positive nitrogen flow. A palladium catalyst (0.04 equivalents) was added to the flask with positive nitrogen flow. The reaction was heated to 80° C. and allowed to proceed for 24 hours. After 24 hours, diphenylamine (0.05 equivalents) was added with positive nitrogen flow. After another hour, bromobenzene (0.1 equivalent) was added to the mixture and allowed to react for another hour, after which the reaction was cooled to room temperature. The reaction mixture was diluted with THE (50% volume relative to toluene) and stirred for a further 15 minutes. The reaction mixture was then precipitated into stirring methanol and the crude polymer was recovered via vacuum filtration. The crude was then dissolved in THE and refluxed overnight with diethylammonium diethyldithiocarbamate (0.3 equivalents, relative to combined fluorenes) believed to be acting as a palladium scavenger. The mixture was cooled to room temperature and again precipitated in stirring methanol. The final polymer was recovered by vacuum filtration and dried in a vacuum oven overnight at 55° C. to afford polymers in various shades of yellow, with yields in excess of 90%.

### Example 16

### Device Fabrication

Glass substrates coated with (pre-patterned) indium tin oxide (ITO) were cleaned in acetone and isopropanol in an ultrasonic bath for 15 minutes each, followed by an additional cleaning step in ozone for 15 minutes immediately before the deposition of a hole transport polymer from Example 15. The hole transport polymer was dissolved with a concentration of 1.5 mg/ml in chlorobenzene. The deposition on top of the ITO front electrode was performed by spin coating at 5,000 rpm for 30 seconds followed by an annealing step at 100° C. for 10 minutes in inert atmosphere.

The perovskite absorber employed in this experiment had the composition Cs_{0.18}FA_{0.82}PbI₃ and was deposited by spin coating. For the perovskite ink, 551.9 mg PbI2, 33.3 mg CsCl, and 191.1 mg FAI were dissolved in a 1 ml mixture of DMF and DMSO (4:1 volume ratio). After all compounds were completely dissolved, 33 μl of a bulk passivation solution were added to the perovskite ink. For the bulk passivation solution, 68 mg PbCl2 and 20 mg phenethylammonium chloride (PEACl) were dissolved in 1 ml DMSO. Finally, the ink was filtered by using a 0.45 μm PVDF filter.

The deposition of the perovskite absorber was performed in a two-step spin-coating approach. After pipetting 150 μl of the perovskite ink and manually spreading it over the substrate, the ink was spun at 1,000 rpm for 10 seconds, followed by a faster spinning at 5,000 rpm for 30 seconds. 10 seconds before the end of the second spin-coating step, 150 μl CB were dropped onto the absorber to initiate nucleation. In order to improve wetting of the perovskite ink on the HTM, poly(9,9-bis(3′-(N,N-dimethyl)-N-ethylammoinium-propyl-2,7-fluorene)-alt-2,7-(9,9-dioctylfluorene))dibromide (PFN-Br) was dynamically spin coated right before the absorber deposition at 5,000 rpm for 20 seconds without further annealing. The absorber was annealed at a temperature of 135° C. for 30 minutes. Right after the annealing, a surface passivation solution (1.5 mg/ml of PEACl in IPA) was dynamically spun on top of the absorber at 5,000 rpm for 30 seconds, followed by an annealing at 100° C. for 5 minutes. All absorber preparation steps were performed in inert environment. To get a working solar cell, 25 nm of C60 and 6 nm of bathocuproine (BCP) were thermal evaporated on top of the absorber and the device equipped with a 100 nm thick silver back electrode that was also thermally evaporated.

### Example 17

### Copolymer Variants of FlAnS

Synthesis of copolymer variants of FlAnS is shown in Equation 6, below.

Copolymers with the following ratios of dihexylfluorene to dimethylfluorene were used to synthesize an HTM; 80:20, 60:40, 50:50, and 40:60. Yields are shown in Table 4, below.

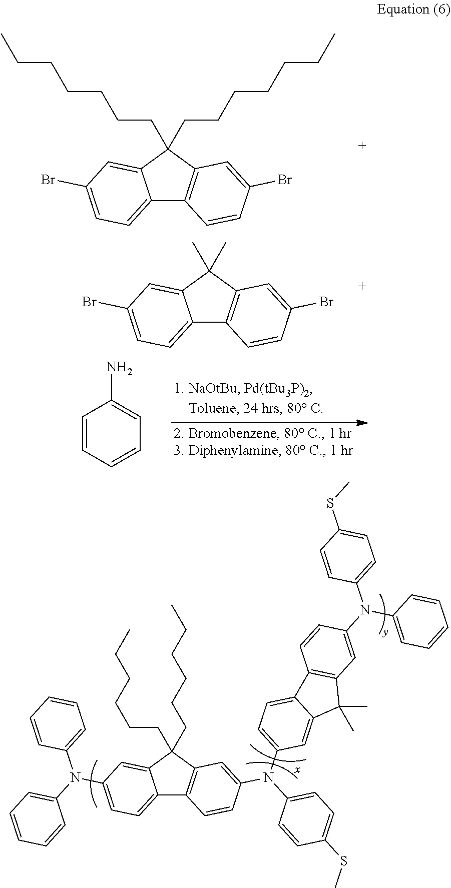

### Example 18

### Copolymer Variants of FlAnS—Thermal Properties

The thermal properties of the copolymers of Example 16 were obtained via TGA and differential scanning calorimetry (DSC). The decomposition temperatures (Td) are based on 5% mass loss and for each material exceed 400° C. (Table 4), which suggests an excellent ability to withstand high operating temperatures.

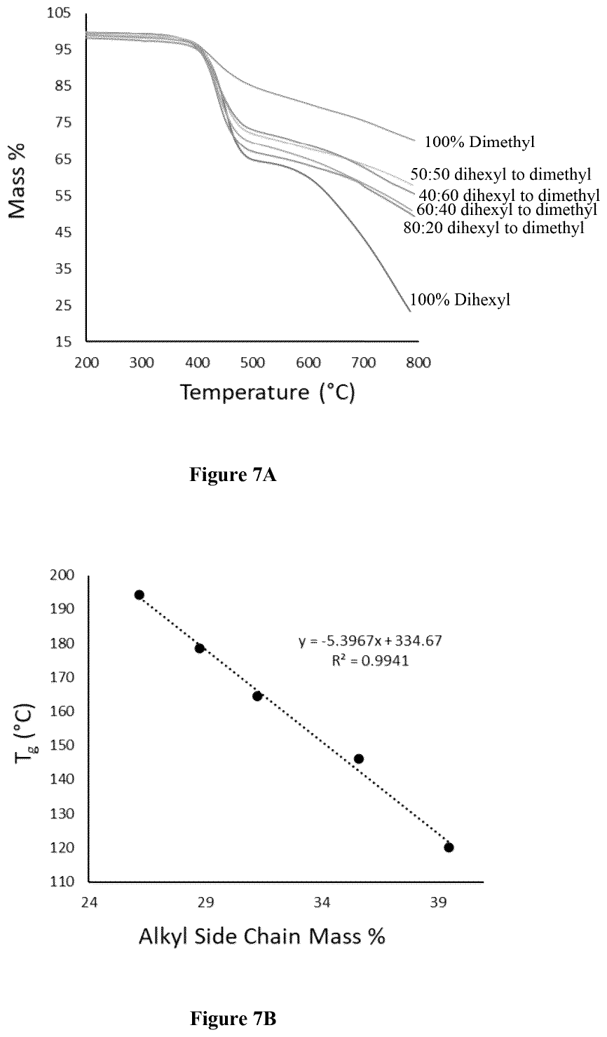

FIG. 7A depicts a plot of mass % loss of the copolymers as temperatures increase. Specifically, FIG. 7A is an overlay of TGA spectra for the copolymers and an FlAnS polymer, demonstrating reduced mass loss as alkyl content decreases. FIG. 7B depicts a plot of % alkyl content versus T_{g}, demonstrating linearly increasing T_{g} as alkyl content decreases.

Without being bound by theory, it is believed the initial mass loss in each of these materials can be attributed to decomposition of the alkyl side chains, which is confirmed by the higher Td values for the copolymers comprising a higher proportion of dimethylfluorene units, which can be clearly observed in FIG. 7A. This trend is also observed for the T_{g} of the copolymers, with a linear increase observed as dimethyl replaces dihexyl as shown in FIG. 7B. This improvement in T_{g} is important for the HTM layer to withstand higher temperatures, for example during the manufacture of devices containing all inorganic perovskites like CsPbI3, or for devices that operate in high temperature environments, such as space applications.

### Example 19

### Copolymer Variants of FlAnS—Molecular Weight and Polydispersity

Polymer properties such as molecular weight and polydispersity are also known to affect the thermal properties of materials. To ensure that this was not the influencing factor in these polymers, gel permeation chromatography (GPC) was performed to determine these properties, which can be seen in Table 4. Each of the polymers demonstrated similar values for weight average molecular weight (Mw), number average molecular weight (Mn), and polydispersity, with the exceptions of the 80:20 copolymer where the GPC chromatogram was bimodal, and the 40:60 polymer which lacked sufficient solubility in the GPC solvent. Nevertheless, these polymers followed the trend for thermal properties and indicated 80:20 and 40:60 incorporation of the fluorene monomers by NMR spectroscopy as expected.

These results showed that the primary factor in improving the T_{g} of the copolymers is decreasing the alkyl side chain mass percentage. In addition, the degree of polymerization was calculated for each polymer using the average monomer mass and number average molecular weight. Based on this polystyrene equivalent molecular weight approach determined via GPC, the range for the polymers was 17 to 20 repeat units, discarding the number for the bimodal 80:20 polymer, which demonstrates a consistent, repeatable polymerization protocol, and should lead to polymers with similar conductivities.

### Example 20

### Copolymer Variants of FlAnS—Optical and Electronic Properties

To ensure that the copolymerization strategy did not affect optical or electronic properties, ultraviolet-visible spectroscopy (UV-Vis) of the copolymers in THE solution was conducted. The UV-Vis spectra suggest that the copolymers have similar properties as the original FlAnS polymer, as no significant shifting of the absorption maxima or UV cut off was observed. Indeed, on calculating the optical bandgap of these materials, no change was observed.

TABLE 4
Thermal, optical, and electronic properties of the synthesized polymers.

| | T_{d} | T_{g} | λₘₐₓ Abs | E_{OBG} | Mₙ | M_{w} | Yield | |
|---|---|---|---|---|---|---|---|---|
| Polymer | (° C.) | (° C.) | (nm) | (eV) | (g mol⁻¹) | (g mol⁻¹) | (%) | PDI |
| FlAnS | 408 | 120 | 411 | 2.90 | 8660 | 42800 | 87 | 4.94 |
| 80:20 | 404 | 146 | 412 | 2.90 | 10800 | 181000 | 94 | 16.8 |
| 60:40 | 406 | 165 | 411 | 2.90 | 7250 | 23600 | 96 | 3.25 |
| 50:50 | 411 | 178 | 411 | 2.90 | 8110 | 37700 | 96 | 4.65 |
| 40:60 | 401 | 194 | 410 | 2.90 | — | — | 93 | — |
| 100% Dimethyl | 413 | — | — | — | — | — | 99 | — |

### Example 21

### Terpolymer Variants of FlAnS

Terpolymer variants of FlAnS were prepared with dihexylfluorene, dimethylfluorene and bis-dimethylaminopropylfluorene monomers. In embodiments, dimethylaminopropyl groups were incorporated at the 9-position, in place of alkyl chains.

The use of functionalized alkyl side chains has been described in literature as a method to passivate metal 2⁺ ions through Lewis basicity, and such side chains should also provide improved ink affinity through hydrogen bonding. The synthesis of bis-dimethylaminopropylfluorene was slightly modified from the method described in Tang et. al., with the synthesis shown in Equation 7A. Due to the gelation of the reaction mixture, the additional heating step was required as this liquified the mixture and allowed the reaction to proceed to completion, which was verified by thin layer chromatography in hexanes and ethyl acetate (4:1 v/v).

The resulting monomer was incorporated into random terpolymers at 5% and 10% ratios, while holding the dimethylfluorene incorporation at 50% as shown in Equation 7B. The resulting yields were 96% and 98% respectively, indicating that incorporation of these monomers was successful. This was verified by ¹H-NMR spectroscopy, and integration of the newly introduced N-methyl peaks confirmed that we had achieved the desired products.

The terpolymers were further characterized in the same manner as the copolymers. Some loss of thermal properties was expected due to the increased branching of the dimethylaminopropyl moiety compared to the dihexyl moiety which it replaced, but surprisingly and unexpectedly, this wasn't the case, as the T_{g} value for both materials was recorded at 183° C., an increase of 5° C. over the 50:50 copolymer. Without being bound by theory, it is believed this is due to the increased strength of the intermolecular forces between the polymer chains, as the introduced tertiary amine allows for increased hydrogen bonding to occur.

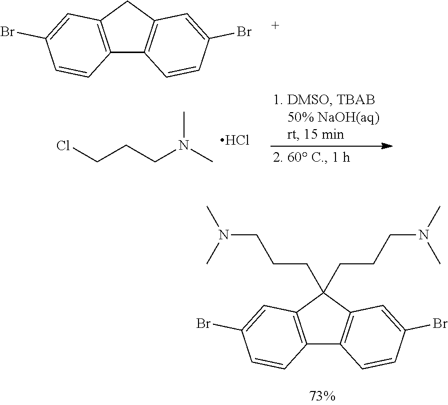

Equation (7A). Synthesis of the monomer 3,3′-(2,7-dibromo-9H-fluorene-9,9-diyl)bis(N,N-dimethylpropan-1-amine).

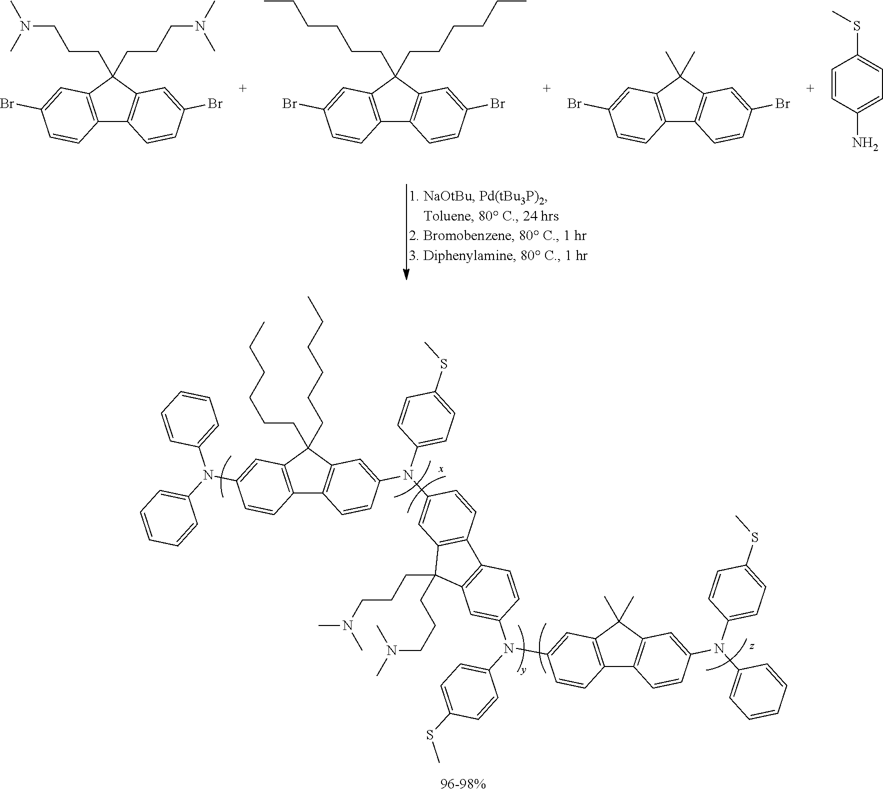

Equation (7B). Polymerization strategy for wettable terpolymers.

### Example 22

### Terpolymer Variants of FlAnS—Electronic Properties

Analysis of the terpolymers was performed to confirm the newly introduced hydrophilic moieties did not affect the electronic properties. From the analysis of UV-Vis spectroscopy, the electronic band gap was determined to be the same as the FlAnS copolymers, with a calculated value of 2.90 eV.

### Example 23

### Terpolymer Variants of FlAnS—Wettability

Wettability was analyzed for the terpolymers and was found to be a concern, as the polymer with 5 wt. % dimethylaminopropyl HTM still required a PFN-Br layer for perovskite deposition, and the 10 wt. % dimethylaminopropyl HTM showed batch-to-batch inconsistencies with wettability which were negated by PFN-Br.

Additional wettable terpolymers were prepared, with the compositions of 40:40:20, 1/3:1/3:1/3, and 25:25:50, of dihexylfluorene, dimethylfluorene and bis-dimethylaminopropylfluorene monomers, respectively. Wettability analysis of the terpolymers is provided in Table 5.

TABLE 5
Terpolymer ratios with electronic properties and contact angle measurements.

| Polymer | | | | E_{BG} | E_{HOMO} | E_{LUMO} | H₂O | Precursor |
|---|---|---|---|---|---|---|---|---|
| Monomer ratio | x | y | z | (eV) | (eV) | (eV) | Contact Angle | Contact Angle |
| 100:0:0 | 100 | 0 | 0 | 2.90 | −5.17 | −2.27 | 95.38° | 52.43° |
| 80:0:20 | 80 | 0 | 20 | 2.90 | −5.19 | −2.29 | 96.7° ± 0.8° | 37.3° ± 0.2° |
| 50:0:50 | 50 | 0 | 50 | 2.90 | −5.19 | −2.29 | 93.5° ± 0.1° | 32.1° ± 0.1° |
| 45:5:50 | 45 | 5 | 50 | 2.90 | −5.16 | −2.26 | 97.3° ± 0.6° | 27.9° ± 1.7° |
| 40:50:10 | 40 | 50 | 10 | 2.90 | −5.16 | −2.26 | 91.7° ± 1.4° | 26.5° ± 0.9° |
| 40:20:40 | 40 | 20 | 40 | 2.90 | −5.16 | −2.26 | 99.2° ± 0.3° | 24.4° ± 0.9° |
| ⅓:⅓:⅓ | ⅓ | ⅓ | ⅓ | 2.90 | −5.28 | −2.38 | 98.1° ± 0.3° | 34.4° ± 0.1° |
| 25:50:25 | 25 | 50 | 25 | 2.90 | −5.17 | −2.27 | 93.6° ± 1.3° | 21.0° ± 0.5° |

### Example 24

### Terpolymer Variants of FlAnS—Photoelectron Spectroscopy in Air (PESA)

Photoelectron spectroscopy in air (PESA) was performed on the polymers created in Examples 21 to 22 to determine highest occupied molecular orbital (HOMO) energies. To ensure consistency in the measurements, a sample of the original 100% dihexyl FlAnS polymer was also tested. This polymer had already been measured at −5.18 eV, 15 and the newly measured value of −5.17 eV is in good agreement with this result. As expected, the incorporation of fluorene monomers with different alkyl side chains led to copolymers and terpolymers with similar HOMO energies, as shown in Table 5, above, with the surprising and unexpected exception of the terpolymer consisting of equal amounts of dimethyl, dihexyl, and bis(dimethylaminopropyl)fluorenes. It was expected that this polymer would have a similar HOMO energy to the other copolymers, and the deeper HOMO energy could indicate contamination of the material, either through the synthetic process, during film preparation, or during transit for PESA testing.

### Example 25

### Terpolymer Variants of FlAnS—Contact Angle

Contact angle testing confirmed that hydrophobicity can be maintained while improving the precursor affinity of the polymer thin films. Each synthesized polymer maintained a water contact angle in excess of 90°, which is excellent for perovskite protection from water ingress. Contact angle measurements were also performed using dimethylformamide (DMF), the solvent used in perovskite processing. As is shown in Table 5, reducing the amount of dihexylfluorene in favor of dimethyl fluorene leads to improved DMF affinity, and additional incorporation of the wettable fluorene monomer leads to further improvement in contact angle as the wettable monomer increases in percentage of total polymer, again with the notable exception of the terpolymer with equal monomer ratios of all three fluorenes. This, coupled with the oddity in PESA data, suggests that this polymer was contaminated in some way.

### Example 26

Terpolymer Incorporation into Devices

The polymers were incorporated into p-i-n devices with the following structure: ITO coated glass/polymer HTM/PFN-Br (optional)/CsFAPbI/C₆₀/BCP/Ag. Initial tests for all HTM materials, including PTAA displayed poor performance, so a bulk passivation step with phenylethylammonium chloride (PEACl) was incorporated, which led to improved performance of the devices. The device performance for all the random copolymers was improved over the performance of both PTAA and the original FlAnS polymer, largely due to improved fill factor (FF) and short circuit current density (Jsc).

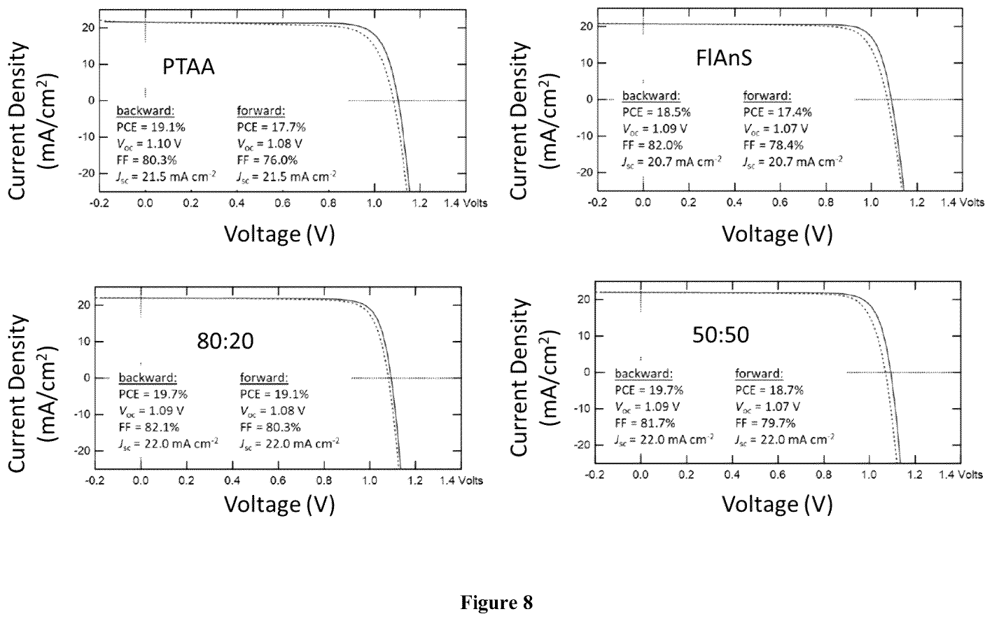

FIG. 8 depicts the J-V curves for devices with PTAA, FlAnS, 50:50, and 80:20 copolymers. The devices associated with FIG. 7 each incorporate a PFN-Br layer between the HTM and the perovskite.

The devices comprising the 80:20 and 50:50 copolymers demonstrated greatly enhanced Jsc with respect to the original FlAnS polymer, with a gain of 1.3 mA cm⁻². This value is linked to the minority carrier lifetime of a material, and while it is unlikely that this value has improved for the copolymers, it is proposed that there is improved intermolecular and intramolecular charge transfer within the HTM due to improved 7L-7L stacking as the alkyl side-chain steric interference is reduced. Without being bound by theory, it is believed to lead to greater conductivity and improved conveyance of charge to the cathode from the perovskite, reducing energy loss pathways.

These improvements from the HTM were still reliant on the PFN-Br interfacial layer for perovskite deposition. The wettable terpolymers allowed direct deposition of the absorber layer, intermittently with the 10 wt. % wettable monomer incorporation, and with good consistency at 20 wt. % incorporation and higher. The resulting devices were able to retain relatively high efficiencies despite a reduction in open circuit voltage (VOC) which was partially offset by improved Jsc. The HTMs comprising 5 wt. % and 10 wt. % wettable monomer were also incorporated into devices comprising PFN-Br, which greatly improved the performance of the 5 wt. % polymer, and allowed slight improvement with the 10 wt. % polymer, largely due to improved VOC. This would suggest that the interfacial layer is vital for controlling the thickness of the absorber layer when used with these materials.

The polymer FlAnS was modified by side chain engineering to improve the material properties of the HTM. These examples demonstrate that the T_{g} value for a polymer was linearly dependent on the mass percentage of the alkyl side chain, with incorporation of a monomer comprising a dimethylaminopropyl side chain improving perovskite precursor wettability and improving T_{g} due to the increased strength of intermolecular forces. The modified HTM polymers demonstrated excellent performance, with improved efficiency over the original FlAnS polymer and PTAA.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

The term “a” or “an” entity refers to one or more of that entity. As such, the terms “a” (or “an”), “one or more,” and “at least one” can be used interchangeably herein. It is also to be noted that the terms “comprising,” “including,” and “having” can be used interchangeably.

It should be understood that every maximum numerical limitation given throughout this disclosure is deemed to include each and every lower numerical limitation as an alternative, as if such lower numerical limitations were expressly written herein. Every minimum numerical limitation given throughout this disclosure is deemed to include each and every higher numerical limitation as an alternative, as if such higher numerical limitations were expressly written herein. Every numerical range given throughout this disclosure is deemed to include each and every narrower numerical range that falls within such broader numerical range, as if such narrower numerical ranges were all expressly written herein. By way of example, the phrase from about 2 to about 4 includes the whole number and/or integer ranges from about 2 to about 3, from about 3 to about 4 and each possible range based on real (e.g., irrational and/or rational) numbers, such as from about 2.1 to about 4.9, from about 2.1 to about 3.4, and so on.

The use of “including,” “comprising,” or “having” and variations thereof herein is meant to encompass the items listed thereafter and equivalents thereof as well as additional items. Accordingly, the terms “including,” “comprising,” or “having” and variations thereof can be used interchangeably herein.

It shall be understood that the term “means” as used herein shall be given its broadest possible interpretation in accordance with 35 U.S.C., Section 112(f). Accordingly, a claim incorporating the term “means” shall cover all structures, materials, or acts set forth herein, and all of the equivalents thereof. Further, the structures, materials, or acts and the equivalents thereof shall include all those described in the Summary, Brief Description of the Drawings, Detailed Description, Abstract, and Claims themselves.

The concepts illustratively disclosed herein suitably may be practiced in the absence of any element which is not specifically disclosed herein. It is apparent to those skilled in the art, however, that many changes, variations, modifications, other uses, and applications of the disclosure are possible, and changes, variations, modifications, other uses, and applications which do not depart from the spirit and scope of the disclosure are deemed to be covered by the disclosure.

The foregoing discussion has been presented for purposes of illustration and description. The foregoing is not intended to limit the disclosure to the form or forms disclosed herein. In the foregoing Detailed Description, for example, various features are grouped together in one or more embodiments for the purpose of streamlining the disclosure. The features of the embodiments may be combined in alternate embodiments other than those discussed above. This method of disclosure is not to be interpreted as reflecting an intention that the claims require more features than are expressly recited in each claim. Rather, as the following claims reflect, inventive aspects lie in less than all features of a single foregoing disclosed embodiment. Thus, the following claims are hereby incorporated into this Detailed Description, with each claim standing on its own as a separate embodiment.

Moreover, though the present disclosure has included description of one or more embodiments and certain variations and modifications, other variations, combinations, and modifications are within the scope of the disclosure, e.g. as may be within the skill and knowledge of those in the art, after understanding the present disclosure. It is intended to obtain rights which include alternative embodiments to the extent permitted, including alternate, interchangeable, and/or equivalent structures, functions, ranges, or steps to those claimed, regardless of whether such alternate, interchangeable, and/or equivalent structures, functions, ranges, or steps are disclosed herein, and without intending to publicly dedicate any patentable subject matter.

1. A hole transport polymer, comprising:
about 0.5 mol % to about 50 mol % of one or more wettable monomers comprising a polycyclic aromatic moiety; and
a second monomer comprising an aromatic amine.

2. The hole transport polymer of claim 1, wherein the one or more wettable monomers comprise at least one oligooxy group and an alkyl side chain comprising four or fewer carbon atoms.

3. The hole transport polymer of claim 2, wherein the at least one oligooxy group is a methoxyethoxy(ethyl) group.

4. The hole transport polymer of claim 1, wherein the aromatic amine moiety comprises at least one of a fluorene monomer and a carbazole monomer.

5. The hole transport polymer of claim 4, wherein the aromatic amine moiety comprises at least one of an amide group, an alkyl group, a phosphine group, an oligoalkyl group, an oligooxy group, an amine group, and a halogen.

6. The hole transport polymer of claim 4, wherein the fluorene monomer is selected from the group comprising dimethylfluorene, dihexylfluorene, dimethylaminopropylfluorene, and dibromofluorene.

7. The hole transport polymer of claim 4, wherein the carbazole monomer is selected from the group comprising dibromocarbazole.

8. The hole transport polymer of claim 1, wherein the one or more wettable monomers comprises at least one wettable dialkylfluorene monomer and a second wettable fluorene monomer, the second wettable fluorene monomer having a side chain comprising at least one of an amide group, a phosphine group, an oligoalkyl group, a halogen, and an amine group.

9. The hole transport polymer of claim 8, wherein the second wettable fluorene monomer is a dimethylaminopropylfluorene monomer.

10. The hole transport polymer of claim 1, wherein the aromatic amine comprises aniline or a derivative thereof.

11. The hole transport polymer of claim 1, further comprising one or more second aromatic amine moieties selected from the group comprising carbazoles, derivatives of carbazoles, fluorenes, derivatives of fluorenes, and combinations thereof.

12. The hole transport polymer of claim 1, having a decomposition temperature of greater than about 350° C.

13. The hole transport polymer of claim 12, wherein the decomposition temperature is greater than about 390° C.

14. The hole transport polymer of claim 1, having a glass transition temperature greater than about 100° C.

15. The hole transport polymer of claim 1, having a highest occupied molecular orbital energy of about −5.4 eV to about −4.9 eV.

16. The hole transport polymer of claim 1, having a lowest unoccupied molecular orbital energy of about −2.5 eV to about −2.0 eV.

17. The hole transport polymer of claim 1, having a water contact angle greater than about 80 degrees.

18. The hole transport polymer of claim 1, wherein the second monomer is hydrophobic.

19. The hole transport polymer of claim 1, wherein the hole transport polymer is synthesized by a Buchwald-Hartwig cross coupling reaction or an Ullmann reaction.

20. A method of manufacturing a perovskite solar cell, comprising:
polymerizing a first quantity of one or more wettable monomers comprising at least one carbazole-containing or fluorene-containing moiety with a second quantity of a monomer comprising an aromatic amine to form a wettable copolymeric hole transport material; and
applying a perovskite solution to the wettable copolymeric hole transport material.

21. The method of claim 20, wherein the applying step is carried out without first applying an interfacial wetting additive to the wettable copolymeric hole transport material.

22. The method of claim 20, wherein, in the applying step, the perovskite solution completely wets the hole transport material to produce a continuous perovskite layer with no defects.

23. A perovskite solar cell, comprising:
a perovskite layer; and
a polymeric hole transport material, comprising a copolymer of (i) one or more wettable monomers comprising at least one carbazole-containing or fluorene-containing moiety and (ii) a monomer comprising an aromatic amine.

24. The perovskite solar cell of claim 23, wherein a decomposition temperature of the polymeric hole transport material is higher than an operating temperature of the perovskite solar cell.

25. The perovskite solar cell of claim 23, wherein a highest occupied molecular orbital energy of the polymeric hole transport material is about equal to a valence band energy of the perovskite layer.

26. A perovskite solar cell, made by the method of claim 20.
